(19) United States
(12) Patent Application Publication
(10) Pub. No.: US 2025/0293179 A1
(43) Pub. Date: Sep. 18, 2025

(54) STACK PACKAGING METHOD FOR MEMORY COMPONENTS FOR SPACE-USE AND MEMORY COMPONENT PACKAGE FOR SPACE-USE MANUFACTURED THROUGH THE METHOD

(71) Applicant: MID CO., LTD, Daejeon (KR)

(72) Inventor: Seong Keun JEONG, Daejeon (KR)

(73) Assignee: MID CO., LTD, Daejeon (KR)

(21) Appl. No.: 18/879,328

(22) PCT Filed: May 24, 2023
(86) PCT No.: PCT/KR2023/007062

§ 371 Date: May 30, 2025

(30) Foreign Application Priority Data
Jun. 28, 2022 (KR) 10-2022-0078577

(51) Int. Cl. H01L 23/556; H01L 25/00; H01L 25/10; H10B 80/00

(52) U.S. Cl. CPC H01L 23/556; H01L 25/105; H01L 25/50; H10B 80/00; H01L 2225/1029

(57) ABSTRACT

A stacked packaging method for a memory component for space applications, according to one embodiment of the present disclosure, may comprise the steps of: forming a parylene-coated memory component by parylene-coating a memory component; forming a stacked memory component by stacking a plurality of the parylene-coated memory component on a lead frame; forming a molded stacked memory component by applying an epoxy molding compound (EMC) to the stacked memory component; forming a stacked memory component module by sawing the molded stacked memory component; electrically connecting the parylene-coated memory components stacked in the stacked memory component module, by printing 3D electrical wiring to the stacked memory component module; and forming a memory component package by parylene-coating the electrically-connected stacked memory component module.

### TECHNICAL FIELD

The present disclosure relates to a stack packaging method of memory components for space applications and a memory component package for space applications manufactured thereby. More specifically, the present disclosure relates to a stack packaging method of memory components for space applications, which enables electrical wiring work to be performed on a stacked memory component module by utilizing a three-dimensional (3D) printer capable of working with a thickness of several nanometers, and a memory component package for space applications manufacture thereby.

### BACKGROUND ART

It is known that about 30% of the malfunctions of electronic equipment sent to space so far are caused by cosmic rays. Cosmic rays in the space environment are classified as high-energy cosmic particles from deep space (galactic cosmic rays), high-energy cosmic particles from the sun (solar cosmic rays), high-energy particle belts captured by the Earth's magnetic field (Van Allen radiation belts), etc., and about 85% of cosmic rays consists of protons.

Further, the cosmic rays collide with the exosphere of the Earth's atmosphere to generate secondary cosmic rays, and then collide with other atmospheric gases to generate a chain of secondary cosmic rays such as neutrons, alphas, betas, gamma rays, etc.

The energy particles of these cosmic rays randomly collide with electronic equipment and affect malfunctions, and as information communication technology (ICT) parts become more highly integrated, concerns about the effect of exposure to high-level cosmic rays are also increasing. In the fields of space, aviation, nuclear power, and medicine that require high reliability, the absence of anti-radiation technology may not only lead to the failure of space exploration missions, but also to the malfunction of social infrastructure, resulting in massive material and human losses.

All parts used in the development of artificial satellites are required to ensure stability and reliability because it is difficult to make additional modifications and corrections during operation of products that have been developed due to the nature of the system.

In advanced countries in the space industry, such as the United States, Europe, Japan, and the like, reliability levels are set for high-reliability space-grade electrical, electronic, and electromechanical (EEE) parts used in satellites, from satellite integration systems to subsystems and unit parts, and very strict quality standards are regulated and required at the national level for all procedures from the production of EEE parts to verification test. The certification test standards for integrated circuits (ICs) most representatively used among the space-grade EEE parts are the United States' MIL-PRF-38535 and Europe's ESCC 9000.

However, since (ultra)small satellites being developed globally, including Starlink, have the characteristics of satellite constellation, such as low-cost and lightweight, constellation operations are being prepared in consideration of the use of commercial off-the-shelf (COTS) parts, satellite weight, satellite shape, mass production, etc.

However, it is difficult to overcome the limitations of packaging systems with weight and spatial constraints such as micro satellites using only existing semiconductor processes.

### DISCLOSURE

### Technical Problem

The present disclosure is directed to providing a stack packaging method of memory components for space applications, which enables electrical wiring work to be performed on a stacked memory component module by utilizing a three-dimensional (3D) printer capable of working with a thickness of several nanometers, and a memory component package for space applications manufacture thereby.

The present disclosure is also directed to providing a stack packaging method of memory components for space applications in which memory components can be parylene-coated to prevent damage to the memory components due to cosmic rays, and a memory component package for space applications manufactured thereby.

The present disclosure is also directed to providing a stack packaging method of memory components for space applications in which a plurality of parylene-coated memory components can be stacked according to a target memory capacity to enable a stacked memory component to be used, and a memory component package for space applications manufactured thereby.

The present disclosure is also directed to providing a stack packaging method of memory components for space applications in which a stacked memory component module can be coated to block cosmic rays, and a memory component package for space applications manufactured thereby.

Technical problems of the present disclosure are not limited to the above-described technical problems and other technical problems that are not described may be clearly understood by those skilled in the art from this specification and the accompanying drawings.

### Technical Solution

This Summary is provided to introduce a selection of concepts in a simplified form that are further described in the Detailed Description below. This Summary is not intended to identify key features or essential features of the claimed subject matter, nor is it intended to be an aid in determining the scope of the claimed subject matter.

One aspect of the present disclosure provides a stack packaging method of memory components for space applications, which includes parylene-coating a memory component to form a parylene-coated memory component, stacking a plurality of parylene-coated memory components identical to the parylene-coated memory component on a lead frame to form a stacked memory component, applying an epoxy molding compound (EMC) to the stacked memory component to form a molded stacked memory component, sawing the molded stacked memory component to form a stacked memory component module, printing three-dimensional (3D) electrical wiring on the stacked memory component module to electrically connect the parylene-coated memory components stacked in the stacked memory component module, and parylene-coating the stacked memory component module in which the parylene-coated memory components are electrically connected to form a memory component package.

Another aspect of the present disclosure provides a memory component package for space applications, which includes a stacked memory component module formed by sawing a molded stacked memory component, wherein the molded stacked memory component is formed by applying an EMC to a stacked memory component, in which a plurality of parylene-coated memory components are stacked, on a lead frame, 3D electrical wiring printed on a plurality of surfaces of the stacked memory component module to electrically connect the parylene-coated memory components stacked in the stacked memory component module, and an outer coated layer formed by coating the stacked memory component module in which the parylene-coated memory components are electrically connected.

Solutions of the present disclosure are not limited to the above-described solutions and other solutions that are not described may be clearly understood by those skilled in the art from this specification and the accompanying drawings.

### Advantageous Effects

According to a stack packaging method of memory components for space applications according to one embodiment of the present disclosure, a three-dimensional (3D) printer capable of working with a thickness of several nanometers can be utilized to enable electrical wiring work to be performed on a stacked memory component module.

According to the stack packaging method of the memory components for space applications according to one embodiment of the present disclosure, by parylene-coating memory components and a stacked memory component module, it is possible to prevent damage to the memory components due to cosmic rays.

According to the stack packaging method of the memory components for space applications according to one embodiment of the present disclosure, a plurality of parylene-coated memory components can be stacked according to a target memory capacity and a stacked memory component can be used.

According to the stack packaging method of the memory components for space applications according to one embodiment of the present disclosure, by coating a stacked memory component module, it is possible to block cosmic rays.

### DESCRIPTION OF DRAWINGS

FIG. 1 is a flowchart for describing a stack packaging method of memory components for space applications according to an exemplary embodiment of the present disclosure.

FIGS. 2 to 8 are views for describing a stack packaging method of memory components for space applications according to an exemplary embodiment of the present disclosure.

FIGS. 9 and 10 are views for describing a memory component package for space applications according to an exemplary embodiment of the present disclosure.

### BEST MODE OF THE INVENTION

The above-described technical problems, features and, advantages of the present disclosure will be clearly understood through the following detailed description taken in conjunction with the accompanying drawings. However, while the present disclosure may have various modifications and alternative forms, specific embodiments thereof are shown by way of example in the drawings and will be described below in detail.

Like numerals refer to, in principle, like elements throughout this specification. Further, elements that have the same function within the scope of the same idea shown in the drawings of each embodiment are described using the same reference numerals, and redundant descriptions thereof will be omitted.

When it is determined that detailed descriptions of related well-known functions or configurations may unnecessarily obscure the gist of the present disclosure, detailed descriptions thereof will be omitted. Further, the ordinal numbers (for example, first, second, etc.) used in description of the specification are used only to distinguish one element from another element.

Further, a suffix “module” or “portion” of an element used herein is assigned or incorporated for convenience of specification description, and the suffix itself does not have a distinct meaning or role.

As used herein, the singular forms “a” and “an” are intended to also include the plural forms, unless the context clearly indicates otherwise.

It will be further understood that the terms “comprise,” “comprising,” “include,” and/or “including” when used herein specify the presence of stated features and elements, but do not preclude the presence or addition of one or more other features and elements.

Sizes of elements in the drawings may be exaggerated for convenience of description. In other words, since sizes and thicknesses of elements in the drawings are arbitrarily illustrated for convenience of description, the present disclosure is not limited thereto.

When a certain embodiment may be implemented differently, a specific process order may be performed differently from the described order. For example, two processes consecutively described may be performed substantially at the same time or performed in an order opposite to the described order.

In the following embodiments, when elements are referred to as being “connected,” it includes “directly connected” and “indirectly connected” via intervening elements.

For example, in this specification, when elements are referred to as being “electrically connected,” it includes “directly electrically connected” and “indirectly electrically connected” via intervening elements.

Among the terms used in this specification, a term “parylene coating” refers to a technology for forming a polymer film using a dimer in powder form using chemical vapor deposition (CVD). The parylene coating is a process for forming a film of nanometer thickness on a subject regardless of its shape by applying heat to a powder dimer in a vacuum chamber to vaporize the powder dimer and diffuse the vaporized dimer inside the chamber.

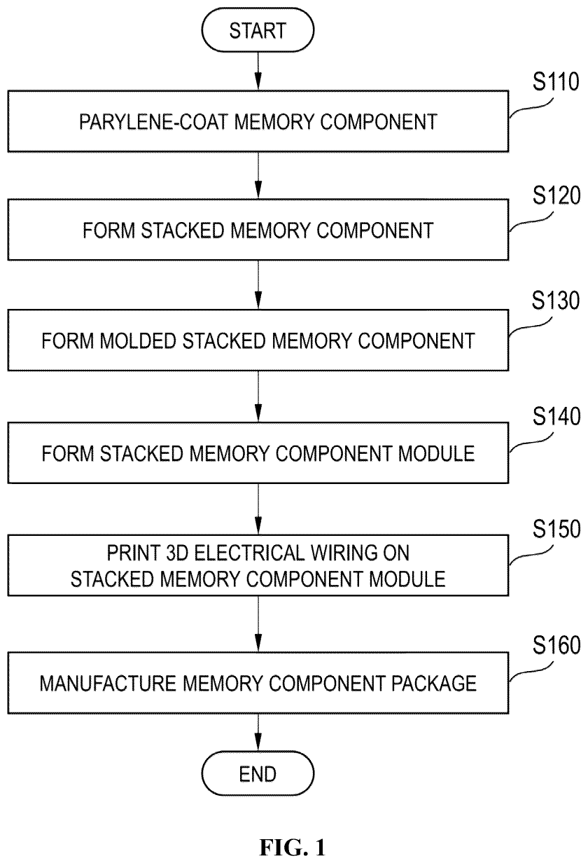

FIG. 1 is a flowchart for describing a stack packaging method of memory components for space applications according to an exemplary embodiment of the present disclosure.

Referring to FIG. 1, first, a memory component is parylene-coated (S110). Specifically, heat is applied to a powder dimer in a vacuum chamber to vaporize the powder dimer, and the vaporized dimer is diffused inside the chamber to form a film of nanometer thickness on the memory component regardless of its shape. Parylene coating may be performed individually on a plurality of memory components. Related memory components may be kitted among parylene-coated memory components. According to an embodiment, a test may be performed on memory components before parylene coating or memory components after parylene coating.

Next, n parylene-coated memory components are stacked on a lead frame to form a stacked memory component (S120). The lead frame is a spider leg-shaped component for electrically connecting a semiconductor chip and a printed circuit board. The lead frame is a support that fixes the semiconductor chip to the printed circuit board and can also acts as a semiconductor substrate itself. When the lead frame acts as a semiconductor substrate, the lead frame is connected to the semiconductor chip by wires. A lead of the lead frame may serve to support a lower portion of the stacked memory component. When the parylene-coated memory components are stacked on such a lead frame, a jig for stacking may be used.

Next, an epoxy molding compound (EMC) is applied to the stacked memory component to form a molded stacked memory component (S130). Specifically, heat is applied to the EMC to liquefy the EMC, and the stacked memory component is sealed with the liquefied EMC. That is, the stacked memory component is encapsulated with the liquefied EMC. Through this encapsulation, the stacked memory component may be protected from an external environment.

Next, the molded stacked memory component is sawed to form a stacked memory component module (S140). According to an embodiment, the molded stacked memory component may be sawed in a vertical direction to have a specific angle with respect to a certain portion of the molded stacked memory component or certain portions of the parylene-coated memory components stacked in the molded stacked memory component. Furthermore, the molded stacked memory component may be sawed in the vertical direction to have a specific angle according to a structure of a container in which the stacked memory component module is contained.

Next, using a three-dimensional (3D) printer (e.g., a DragonFly IV 3D printer), 3D electrical wiring is printed on at least three surfaces of the stacked memory component module. As a result, the parylene-coated memory components stacked in the stacked memory component module are electrically connected (S150).

Here, printing the 3D electrical wiring means forming electrical wiring by printing conductive ink or a conductive paste on at least three surfaces of the stacked memory component module. According to an embodiment, the three surfaces may include one top surface and two side surfaces.

Conductive ink is a material that usually disperses metal particles with a diameter of several nanometers to several tens of micrometers in a solvent. When the conductive ink is printed on a substrate and heat is applied to the printed conductive ink at a predetermined temperature, organic additives such as dispersing agents and the like are volatilized, air gaps between the metal particles shrink and are sintered, and thus conductors that are electrically and mechanically connected to each other are formed.

The conductive ink may further include other additives such as additional organic solvents, binders, dispersing agents, thickening agents, surfactants, etc., as necessary, and these other additives are known to those skilled in the art.

Meanwhile, a conductive paste is generally a material that disperses metal particles with a diameter of several nanometers to several tens of micrometers in an adhesive resin. When the conductive paste is printed on a substrate and heat is applied to the printed conductive paste at a predetermined temperature, a resin is cured, an electrical and mechanical contact between the metal particles is fixed, and thus conductors that are electrically connected to each other may be formed.

The conductive paste includes particles of an electrically conductive material. Examples of electrically conductive material may include powders of conductive metals, non-metals or their oxides, carbides, borides, nitrides, carbon nitrides, and carbon-based powders such as carbon black, graphite, etc.

The particles of the conductive paste may include, for example, gold, aluminum, copper, indium, antimony, magnesium, chromium, tin, nickel, silver, iron, titanium, and alloys thereof, and oxides, carbides, borides, nitrides and carbonitrides thereof.

The shape of the particles of the conductive paste is not particularly limited, and for example, plate-shaped, fiber-shaped, and nano-sized nanoparticles, nanotubes, etc., may be used. These particles of the conductive paste may be used alone or in combination.

Further, the conductive paste may additionally include a binder to improve adhesion to the substrate. Generally, an organic binder such as an epoxy resin, a phenol resin (phenol+formaldehyde), a polyurethane resin, a polyamide resin, an acrylic resin, a urea/melamine resin, a silicone resin, or the like may be used as the binder. However, when a wiring layer is formed with a conductive paste including an organic binder and then chemical plating is formed, a plating solution may penetrate into the wiring layer, causing a circuit layer to be separated, and a strong base contained in chemical plating may dissolve an acrylic binder, causing many problems. Therefore, it is preferable to use an epoxy binder rather than an organic binder.

The content of a binder may generally range from 10 to 80 wt % relative to a total paste composition, and preferably, range from 20 to 70 wt %, but the present disclosure is not limited thereto. As described above, the binder acts as a cause of reducing the electrical conductivity of the wiring layer including the conductive paste.

The conductive ink or conductive paste described above may be directly printed on the stacked memory component module to form a patterned wiring layer with a shape desired by a user.

The direct printing method may be performed continuously by a printing method. Further, examples of the direct printing method may include flat or roll-to-roll screen printing, rotary printing, flexography (or flexographic printing), gravure printing, gravure-offset printing, reverse-offset printing, polymer gravure printing, imprinting, inkjet printing, micro gravure, slot die coating, pad printing, and dispenser printing. Preferably, flat screen printing, roll-to-roll screen printing, rotary screen printing, gravure printing, or gravure-offset printing may be used.

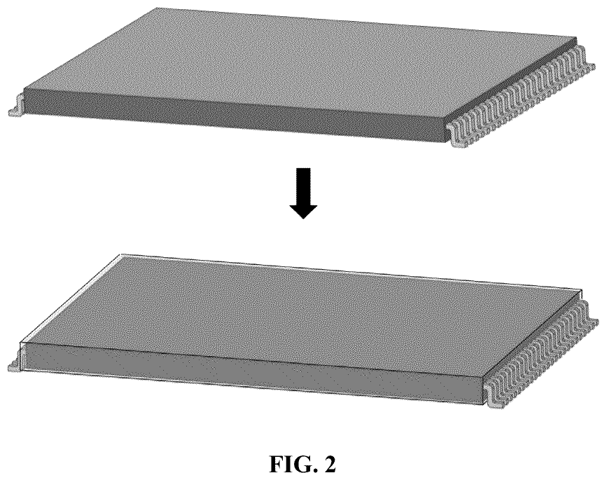

FIGS. 2 to 8 are views for describing a stack packaging method of memory components for space applications according to an exemplary embodiment of the present disclosure.

First, a memory component is parylene-coated to form a parylene-coated memory component. Specifically, heat is applied to a powder dimer in a vacuum chamber to vaporize the powder dimer, and the vaporized dimer is diffused inside the chamber to form a film of nanometer thickness on the memory component regardless of its shape. FIG. 2 illustrates such a parylene coating process, wherein an upper figure of FIG. 2 is a perspective view of a memory component before parylene-coating, and a lower figure of FIG. 2 is a perspective view of a memory component after parylene coating.

Parylene coating may be performed individually on a plurality of memory components. In addition, related memory components may be kitted among parylene-coated memory components. Further, a test may be performed on memory components before parylene coating or memory components after parylene coating.

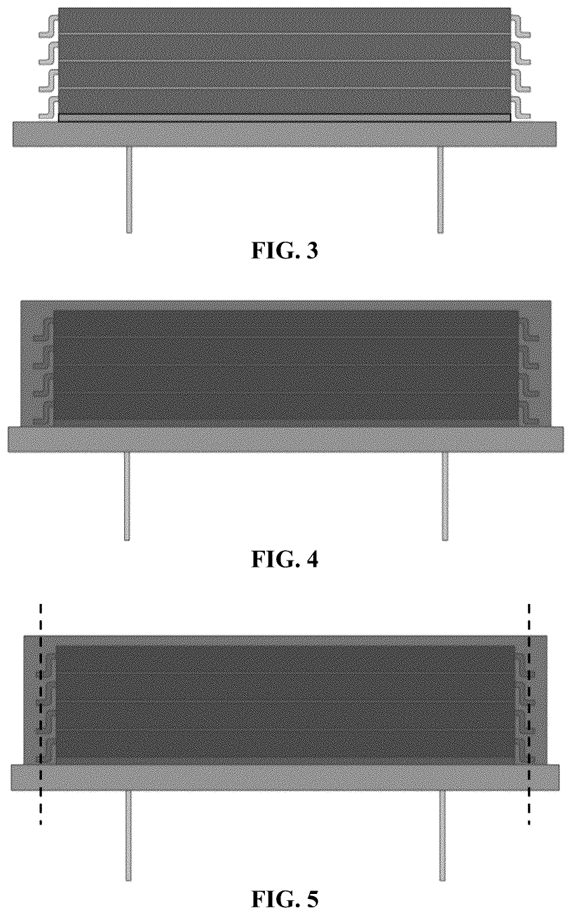

Thereafter, a plurality of parylene-coated memory components are stacked on a lead frame to form a stacked memory component. In this case, the plurality of the parylene-coated memory components corresponding to a target memory capacity may be stacked. Further, when the parylene-coated memory components are stacked, a jig for stacking may be used. A side sectional view of the stacked memory component formed in the above-described manner is as illustrated in FIG. 3.

Next, an EMC is applied to the stacked memory component to form a molded stacked memory component. In this way, the reason why the parylene-coated memory components are stacked on the lead frame before the EMC is applied is to form a molding only on the parylene-coated memory components. A side sectional view of the molded stacked memory component formed in the above-described manner is as illustrated in FIG. 4.

Next, the molded stacked memory component is sawed to form a stacked memory component module. Sawing may be understood as a process for generating bare connections. According to an embodiment, the molded stacked memory component may be sawed in a vertical direction to have a specific angle with respect to a certain portion of the molded stacked memory component or certain portions of the parylene-coated memory components stacked inside the molded stacked memory component. An example of the sawing direction that can be applied to the molded stacked memory component is illustrated in FIG. 5. In FIG. 5, the sawing direction is illustrated by a dotted line. Referring to the dotted line, it can be seen that the sawing direction is a direction that penetrates leads of the parylene-coated memory components stacked inside the molded stacked memory component. Therefore, when the molded stacked memory component is sawed along a corresponding dotted line, connections inside the molded stacked memory component are exposed.

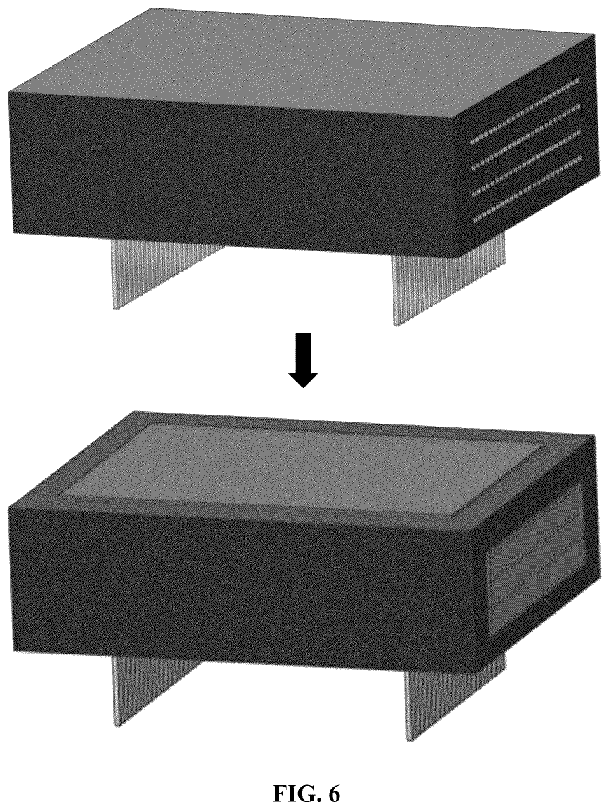

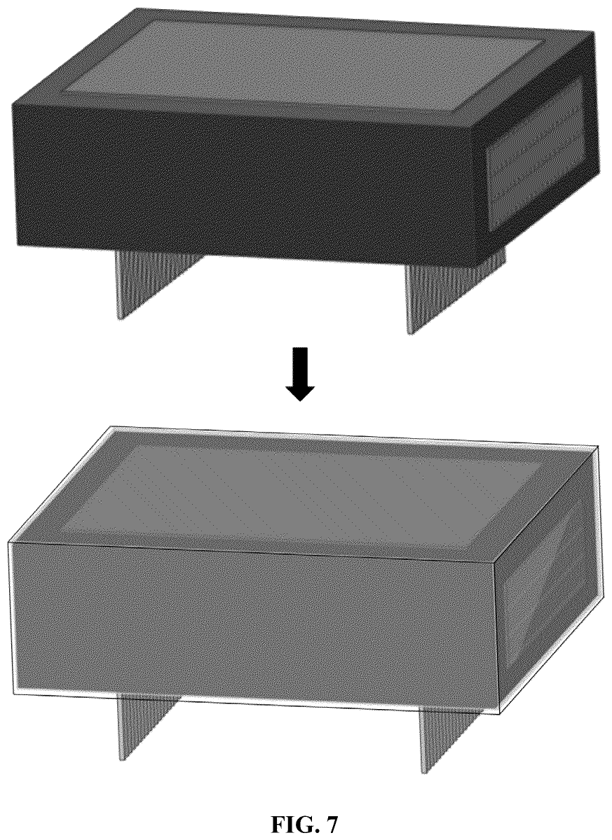

An upper figure of FIG. 6 is a perspective view of a stacked memory

component module obtained by sawing. Referring to the upper figure of FIG. 6, it can be seen that exposed connections are formed on left and right sides of the stacked memory component module. According to an embodiment, plating of a cold process may be performed on the stacked memory component module on which the exposed connections are formed.

Thereafter, a 3D printer is used to print 3D electrical wiring on the plated stacked memory component module. For example, laser engraving is performed using a 3D printer to form an edge connection with a bus metal. As a result, the parylene-coated memory components stacked in the stacked memory component module may be electrically connected. A perspective view of the stacked memory component module in which the parylene-coated memory components are electrically connected is as illustrated in a lower figure of FIG. 6.

According to an embodiment, an example of the 3D printer may include a DragonFly IV 3D printer. However, the 3D printer is not necessarily limited thereto, and any 3D printer capable of wiring work with a thickness of several nanometers may be applied to the present disclosure.

According to an embodiment, 3D electrical wiring may be printed on at least three surfaces of the stacked memory component module. Further, the parylene-coated memory components stacked in the stacked memory component module may be electrically connected by a specific number of through-vias (TVs).

Further, the stacked memory component module may further include internal connection terminals for electrically coupling to each other. The internal connection terminals may be aligned with respect to the TVs. Furthermore, the stacked memory component module may further include a conductive bump, a solder ball, or a conductive spacer.

Meanwhile, among the parylene-coated memory components included in the stacked memory component module, the parylene-coated memory component formed on the uppermost side may be used as a top plate, and the parylene-coated memory component formed on the lowermost side may be used as a ground plane. Therefore, in the case in which 3D electrical wiring is printed on at least three surfaces of the stacked memory component module, when a short-circuit pin is formed on the parylene-coated memory component used as the ground plane, the stacked memory component module may be electrically connected to the lead frame through the short-circuit pin.

Thereafter, the stacked memory component module in which the parylene-coated memory components are electrically connected is parylene-coated. That is, heat is applied to the powder dimer in the vacuum chamber to vaporize the powder dimer, and the vaporized dimer is diffused inside the chamber to form a film of nanometer thickness on the stacked memory component module regardless of its shape. Before performing the parylene coating on the stacked memory component module, a soldering lead portion may be treated with a coating mask. FIG. 7 illustrates a parylene coating process for a stacked memory component, wherein an upper figure of FIG. 7 is a perspective view of a stacked memory component module before parylene coating, and a lower figure of FIG. 7 is a perspective view of a stacked memory component module after parylene coating.

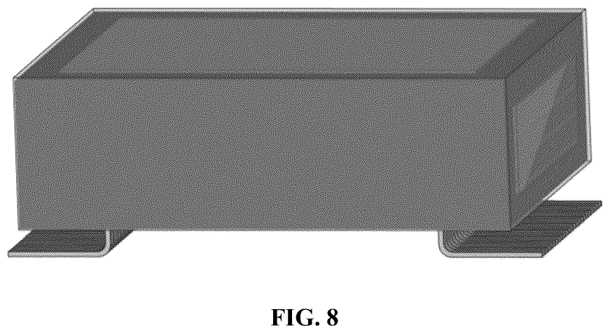

Thereafter, protruding leads are bent through lead forming to manufacture a memory component package as illustrated in a perspective view of FIG. 8.

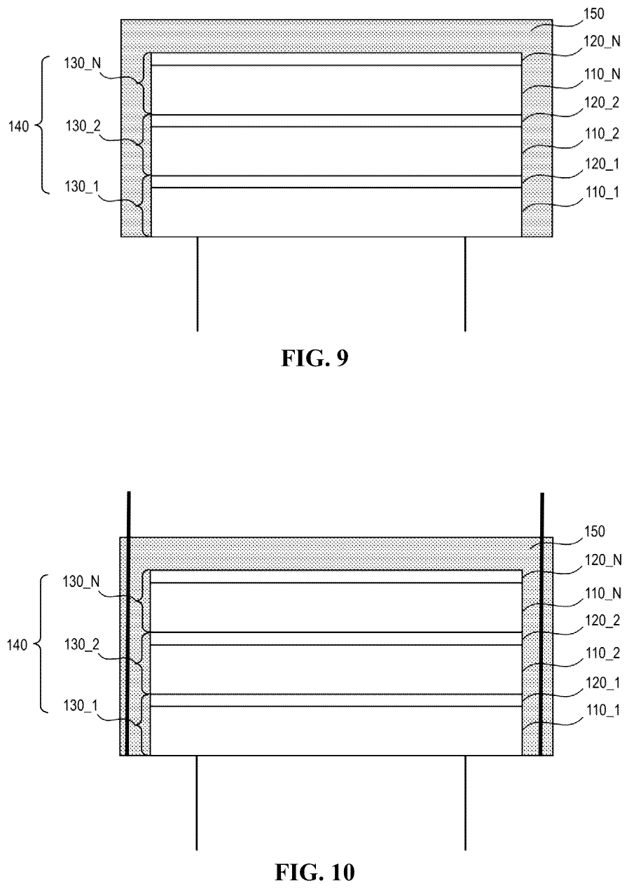

FIGS. 9 and 10 are views for describing a memory component package for space applications according to an exemplary embodiment of the present disclosure. In FIGS. 9 and 10, some components described above are omitted.

Referring to side cross-sectional views of FIGS. 9 and 10, the memory component package for space applications includes a stacked memory component 140 in which parylene-coated memory components are stacked, a molding 150 of the stacked memory component 140, 3D electrical wiring, and an outer coated layer.

The stacked memory component 140 is formed through a process for performing parylene coating to form parylene coated layers 120_1 to 120_N on memory components 110_1 to 110_N and a process for stacking a plurality of parylene-coated memory components 130_1 to 130_N on a lead frame (not illustrated). According to an embodiment, the parylene-coated memory components 130_1 to 130_N corresponding to a target memory capacity may be stacked on the lead frame.

The molding 150 of the stacked memory component 140 may be formed by applying an EMC to the stacked memory component 140. Specifically, heat is applied to the EMC to liquefy the EMC, and the liquefied EMC may be applied to the stacked memory component 140 to form the molding 150 of the stacked memory component 140. In this way, the reason why the stacked memory component 140 is positioned on the lead frame before forming the molding 150 of the stacked memory component 140 is to form the molding only on the stacked memory component 140.

After the molding 150 of the stacked memory component 140 is formed, the molded stacked memory component 150 is sawed as illustrated in FIG. 10 to form a stacked memory component module. According to an embodiment, the molded stacked memory component 150 may be sawed in a vertical direction to have a specific angle with respect to a certain portion of the molded stacked memory component 150 or certain portions of the parylene-coated memory components stacked inside the molded stacked memory component 150.

The 3D electrical wiring may be printed on the stacked memory component module formed by the above-described method. According to an embodiment, the 3D electrical wiring may be printed on at least three surfaces of the stacked memory component module. For example, the 3D electrical wiring may be printed on a top surface and at least two side surfaces of the stacked memory component module. As a result, the parylene-coated memory components stacked in the stacked memory component module may be electrically connected.

Meanwhile, the outer coated layer may be formed by coating the stacked memory component module in which the parylene-coated memory components are electrically connected.

The features, structures, effects, etc., described in the embodiments above are included in at least one embodiment of the present disclosure, and are not necessarily limited to only one embodiment. Furthermore, the features, structures, effects, etc. exemplified in each embodiment may be combined or modified and implemented in other embodiments by those skilled in the art to which the embodiments belong. Therefore, the content related to such combinations and modifications should be interpreted as being included in the scope of the present disclosure.

In addition, while the present disclosure has been particularly described with reference to embodiments, the embodiments are only exemplary embodiments of the present disclosure and the present disclosure is not intended to be limited thereto. It will be understood by those skilled in the art that modifications and applications in other forms may be made without departing from the spirit and scope of the present disclosure. That is, each component specifically shown in the embodiments may be modified and embodied. In addition, it should be understood that differences related to these modifications and applications are within the scope of the present disclosure as defined in the appended claims.

### INDUSTRIAL APPLICABILITY

The stack packaging method of the memory components for space applications described above may be applied to the field of manufacturing memory component packages.

1. A stack packaging method of memory components for space applications, comprising:
parylene-coating a memory component to form a parylene-coated memory component;
stacking a plurality of parylene-coated memory components identical to the parylene-coated memory component on a lead frame to form a stacked memory component;
applying an epoxy molding compound (EMC) to the stacked memory component to form a molded stacked memory component;
sawing the molded stacked memory component to form a stacked memory component module;
printing three-dimensional (3D) electrical wiring on the stacked memory component module to electrically connect the parylene-coated memory components stacked in the stacked memory component module; and
parylene-coating the stacked memory component module in which the parylene-coated memory components are electrically connected to form a memory component package.

2. The method of claim 1, wherein the forming of the stacked memory component includes forming the stacked memory component by stacking the plurality of the parylene-coated memory components corresponding to a target memory capacity on the lead frame.

3. The method of claim 1, wherein the forming of the stacked memory component module includes forming the stacked memory component module by sawing the molded stacked memory component in a vertical direction to have a specific angle with respect to a certain portion of the molded stacked memory component or certain portions of the parylene-coated memory components stacked in the molded stacked memory component.

4. The method of claim 1, wherein the electrically connecting of the parylene-coated memory components stacked in the stacked memory component module includes electrically connecting the parylene-coated memory components stacked in the stacked memory component module by printing the 3D electrical wiring on at least three surfaces of the stacked memory component module.

5. A memory component package for space applications, comprising:
a stacked memory component module formed by sawing a molded stacked memory component, wherein the molded stacked memory component is formed by applying an epoxy molding compound (EMC) to a stacked memory component, in which a plurality of parylene-coated memory components are stacked, on a lead frame:
three-dimensional (3D) electrical wiring printed on a plurality of surfaces of the stacked memory component module to electrically connect the parylene-coated memory components stacked in the stacked memory component module; and
an outer coated layer formed by coating the stacked memory component module in which the parylene-coated memory components are electrically connected.

6. The memory component package of claim 5, wherein the lead frame includes a lead that supports a lower portion of the molded stacked memory component.

7. The memory component package of claim 5, wherein the stacked memory component module is formed by sawing the molded stacked memory component in a vertical direction to have a specific angle with respect to a certain portion of the molded stacked memory component or certain portions of the parylene-coated memory components stacked in the molded stacked memory component.

8. The memory component package of claim 5, wherein the 3D electrical wiring is printed on a top surface and at least two side surfaces of the stacked memory component module.
